(19) United States
(12) Patent Application Publication
(10) Pub. No.: US 2024/0355673 A1
(43) Pub. Date: Oct. 24, 2024

(54) HYBRID MOLYBDENUM FILL SCHEME FOR LOW RESISTIVITY SEMICONDUCTOR APPLICATIONS

(71) Applicant: Applied Materials, Inc., Santa Clara, CA (US)

(72) Inventors: Wei LEI, Santa Clara, CA (US); Sahil PATEL, Sunnyvale, CA (US); Yixiong YANG, Fremont, CA (US); Yu LEI, Belmont, CA (US); Shiyu YUE, Santa Clara, CA (US); Yi XU, San Jose, CA (US); Tuerxun AILIHUMAER, Santa Clara, CA (US); Juhyun OH, San Jose, CA (US); Xianmin TANG, San Jose, CA (US); Rongjun WANG, Dublin, CA (US)

(21) Appl. No.: 18/136,970

(22) Filed: Apr. 20, 2023

(51) Int. Cl. H01L 21/768; H01L 23/522; H01L 23/532

(52) U.S. Cl. CPC H01L 21/76843; H01L 21/76877; H01L 23/5226; H01L 23/53266; C23C 14/18; H01L 21/02063; H01L 21/28568

(57) ABSTRACT

Semiconductor devices and methods for molybdenum fill in semiconductor devices are provided. In one aspect, a method for processing a semiconductor device substrate is provided. The method includes exposing at least one feature formed in a dielectric layer to a grain modification layer deposition process to deposit a grain modification layer over at least a portion of the at least one feature. The at least one feature is defined by sidewall surfaces formed in the dielectric layer and a bottom surface extending between the sidewall surfaces. The method further includes exposing the at least one feature to a molybdenum deposition process to form a molybdenum-fill layer on the grain modification layer, wherein the grain modification layer comprises a metal different from molybdenum.

### BACKGROUND

### Field

The present disclosure generally relates to a method and apparatus for forming thin-films. More particularly, the disclosure relates to a method and apparatus for molybdenum fill in semiconductor devices.

### Description of the Related Art

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each operation is time consuming and expensive.

With ever-decreasing critical dimensions for the microelectronic devices, the design and fabrication for these devices on substrates becomes increasingly complex. Control of the critical dimensions and process uniformity becomes increasingly more significant. Complex multilayer stacks involve precise process monitoring of the critical dimensions for the thickness, roughness, stress, density, and potential defects. Multiple incremental processes in the process recipes for forming the devices ensure critical dimensions are maintained. However, each recipe process may utilize one or more processing chambers that adds additional time for forming the devices in the processing systems and also provides additional opportunities for forming defects. Thus, each process adds to the overall fabrication cost for the completed microelectronic devices.

Additionally, as critical dimensions on devices shrink and high aspect ratio features become more come, it has become increasingly difficult to fill high aspect ratio features using current fabrication techniques.

For at least the foregoing reasons, there is an ongoing need for improved fabrication methods to minimize cost while maintaining critical dimensions for microelectronic devices.

### SUMMARY

The present disclosure generally relates to a method and apparatus for forming thin-films. More particularly, the disclosure relates to a method and apparatus for molybdenum fill in semiconductor devices.

In one aspect, a method for processing a semiconductor device substrate is provided. The method includes exposing at least one feature formed in a dielectric layer to a grain modification layer deposition process to deposit a grain modification layer over at least a portion of the at least one feature. The at least one feature is defined by sidewall surfaces formed in the dielectric layer and a bottom surface extending between the sidewall surfaces. The method further includes exposing the at least one feature to a molybdenum deposition process to form a molybdenum-fill layer on the grain modification layer, wherein the grain modification layer comprises a metal different from molybdenum.

Implementations may include one or more of the following. The grain modification layer deposition process is a physical vapor deposition (PVD) process and the metal comprises tungsten. The molybdenum deposition process is a physical vapor deposition (PVD) process. The molybdenum deposition process includes a vapor deposition process performed in a deposition chamber. The vapor deposition process includes introducing a molybdenum chloride precursor, a molybdenum oxyhalide precursor, or a combination thereof into the deposition chamber. The vapor deposition process further includes introducing a reducing agent precursor gas into the deposition chamber. The reducing agent precursor gas is selected from molecular hydrogen (H₂), hydrogen atoms, a hydrogen plasma, hydrogen radicals, hydrogen excited species or a combination thereof. The vapor deposition process includes introducing H2 and MoCl5 into the deposition chamber. The bottom surface is defined by the dielectric layer. The bottom surface is defined by a silicide layer, a metal silicide layer, or a metal layer.

In another aspect, a method for processing a semiconductor device structure is provided. The method includes exposing at least one feature formed in a dielectric layer formed over a substrate to a physical vapor deposition (PVD) process to deposit a grain modification layer comprising tungsten over at least a portion of the at least one feature. The PVD process is performed in a first processing region of a first processing chamber and the at least one feature is defined by sidewall surfaces formed in the dielectric layer and a bottom surface extending between the sidewall surfaces. The method further includes transferring the substrate from the first processing region of the first processing chamber to a second processing region of a second processing chamber without breaking vacuum. The method further includes exposing the feature to a vapor deposition process comprising flowing a molybdenum-containing precursor gas into the second processing region to form a molybdenum-fill layer on the grain modification layer within the at least one feature in the second processing region.

Implementations may include one or more of the following. The molybdenum-containing precursor gas is selected from a molybdenum chloride precursor, a molybdenum oxyhalide precursor, or a combination thereof. The vapor deposition process further includes introducing a reducing agent precursor gas into the deposition chamber. The reducing agent precursor gas is selected from molecular hydrogen (H₂), hydrogen atoms, a hydrogen plasma, hydrogen radicals, hydrogen excited species or a combination thereof. The vapor deposition process comprises introducing H2 and MoCl5 into the second processing region. The vapor deposition process is performed at a temperature in a range from about 400° C. to about 500° C. at a pressure in a range from about 1 Torr to about 100 Torr. The vapor deposition process is a chemical vapor deposition (CVD) process, an atomic layer deposition (ALD) process, or a plasma-enhanced ALD process.

In yet another aspect, a semiconductor device structure is provided. The semiconductor device structure includes a device substrate having a frontside and a backside. The semiconductor device structure further includes a dielectric layer formed over the device substrate. The dielectric layer has at least one feature formed therein, the at least one feature defined by sidewall surfaces defined by the dielectric layer and a bottom surface extending between the sidewall surfaces. The semiconductor device structure further includes a grain modification layer comprising tungsten formed on at least the bottom surface of the feature. The semiconductor device structure further includes a molybdenum-fill material contacting the grain modification layer and filling the feature.

Implementations may include one or more of the following. The grain modification layer has a thickness in a range from about 10 Å to about 50 Å. The bottom surface is defined by the dielectric layer and the grain modification layer is formed on the sidewall surfaces defined by the dielectric layer. The bottom surface is defined by a metal layer.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic top view of one example of a multi-chamber processing tool in accordance with one or more implementations of the present disclosure.

FIGS. 2A-2B illustrate flow charts of a method for manufacturing a semiconductor device in accordance with one or more implementations of the present disclosure.

FIGS. 3A-3E illustrate views of various stages of manufacturing a semiconductor device in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure generally relates to a method and apparatus for forming thin-films. More particularly, the disclosure relates to a method and apparatus for molybdenum fill in semiconductor devices.

Low resistivity metal contact fill is looked-for to drive device scaling. However, the deposition of metal contact fill thin films in features with ultra-high aspect ratios is challenging. Molybdenum is considered as a candidate to replace tungsten because of molybdenum's lower resistivity. The resistivity of molybdenum may be dependent upon the substrate on which the molybdenum is grown. For example, the substrate on which the molybdenum is grown may affect the grain size and thus the resistivity of the subsequently formed molybdenum material. Some structures have no contact metal at the bottom, or the contact metal may not be ideal to grow low resistivity molybdenum. Thus, there is a need for improved methods for growing low resistivity molybdenum.

Various implementations provide processes for improved molybdenum-fill in features having reduced critical dimensions. Various implementations provide a grain modification layer for modifying the grain size of the subsequently deposited molybdenum material. The grain modification layer may be or include a metal layer, for example, a tungsten layer or a cobalt layer. The grain modification layer may be a conformal layer. The grain modification layer may be a nonconformal layer. Not to be bound by theory but it is believed that larger molybdenum grain size is preferable to achieve low resistivity and this larger grain size is achievable using grain modification layers such as tungsten. The grain modification layer may be deposited using techniques such as physical vapor deposition (PVD), chemical vapor deposition (CVD), atomic layer deposition (ALD), or hybrid ALD/CVD techniques. The molybdenum-fill may be deposited by CVD or PVD. The molybdenum-fill may be bottom-up or conformal. The processes described can achieve low resistivity molybdenum-fill regardless of structure type, for example, a via with a metal contact or a trench which has no metal contact.

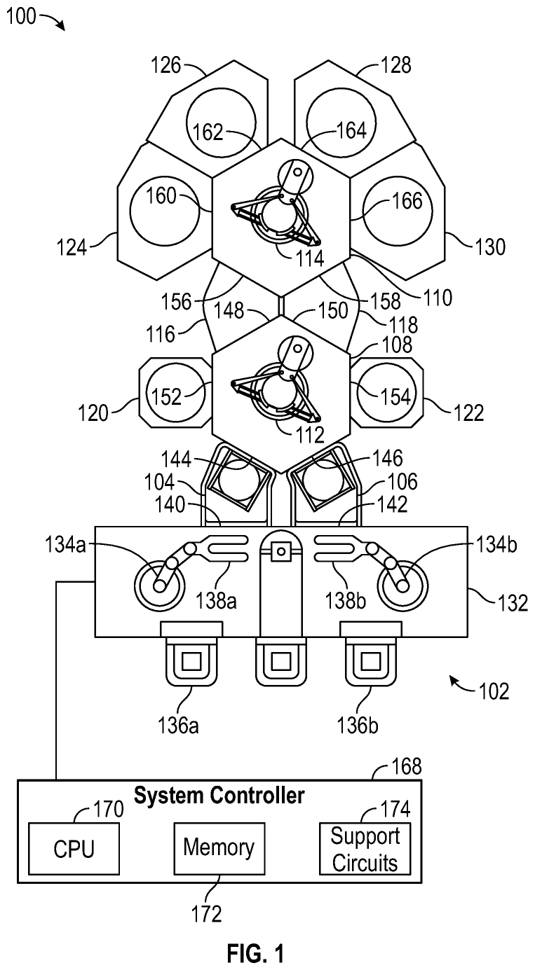

FIG. 1 illustrates a schematic top view of a multi-chamber processing system 100 in accordance with one or more implementations of the present disclosure. The processing system 100 can be used for deposition of a grain modification layer followed by seamless gap-fill of molybdenum without breaking vacuum in accordance with one or more implementations of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the processing system 100. Accordingly, the processing system 100 may provide for an integrated solution for processing of substrates.

Examples of processing systems that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chambers 108, 110, the holding chambers 116, 118, and the processing chambers 120, 122, 124, 126, 128, 130 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chambers 108, 110 and the holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber, Volta™ CVD/ALD chamber, or Encore™ PVD chambers available from Applied Materials of Santa Clara, Calif.

A system controller 168 is coupled to the processing system 100 for controlling the processing system 100 or components thereof. For example, the system controller 168 may control the operation of the processing system 100 using a direct control of the processing chambers 104, 106, 108, 110, 116, 118, 120, 122, 124, 126, 128, 130 of the processing system 100 or by controlling controllers associated with the processing chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 168 is configured to perform methods such as the method 200A stored in the memory 172.

In particular implementations, at least one of the processing chambers 120 and 122 is a pre-clean chamber configured to perform the pretreatment process of operation 220, at least one of the processing chambers 124, 126, 128, 130 is a PVD chamber configured to perform the PVD tungsten deposition process of operation 230 of the methods 200A, and another of the processing chambers the chambers 124, 126, 128, 130 is a CVD chamber configured to perform the molybdenum deposition process of operation 240 of the method 200A without breaking vacuum between any of the operations 210-230.

In operation, a substrate having a feature formed therein may be transferred to a first processing chamber which is one of the processing chambers 122 and 124 where the feature is exposed to a pretreatment process to remove, for example, native oxides formed on the feature. The substrate may then be transferred to a second processing chamber which is one of the processing chamber 124, 126, 128, and 130 without breaking vacuum where a grain modification layer, for example, a tungsten layer, is deposited over the feature. The substrate may then be transferred to a third processing chamber which is one of the processing chambers 124, 126, 128, and 130 without breaking vacuum, where molybdenum is deposited on the grain modification layer.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (for example, one transfer chamber) and/or more or fewer holding chambers (for example, no holding chambers) may be implemented as a transfer apparatus in a processing system.

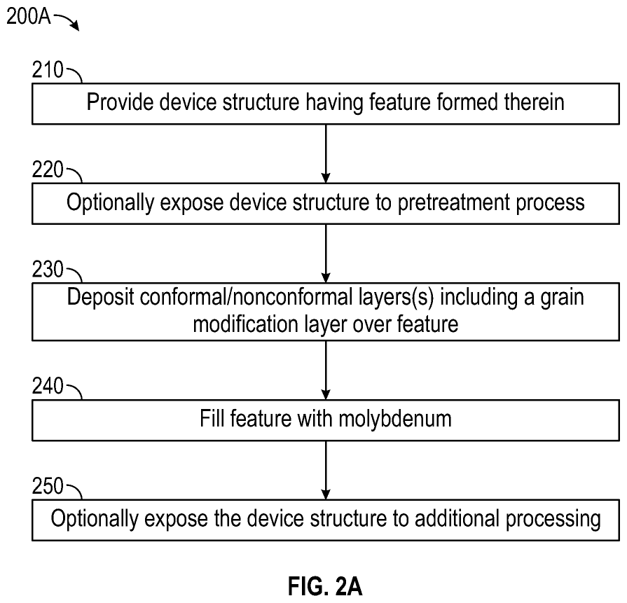

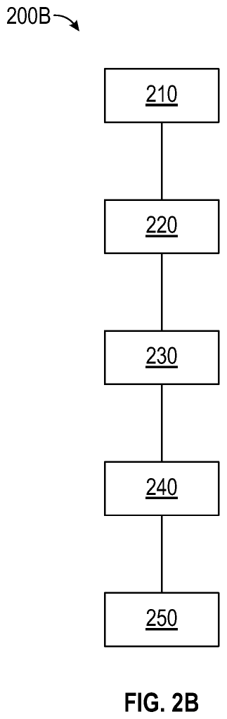

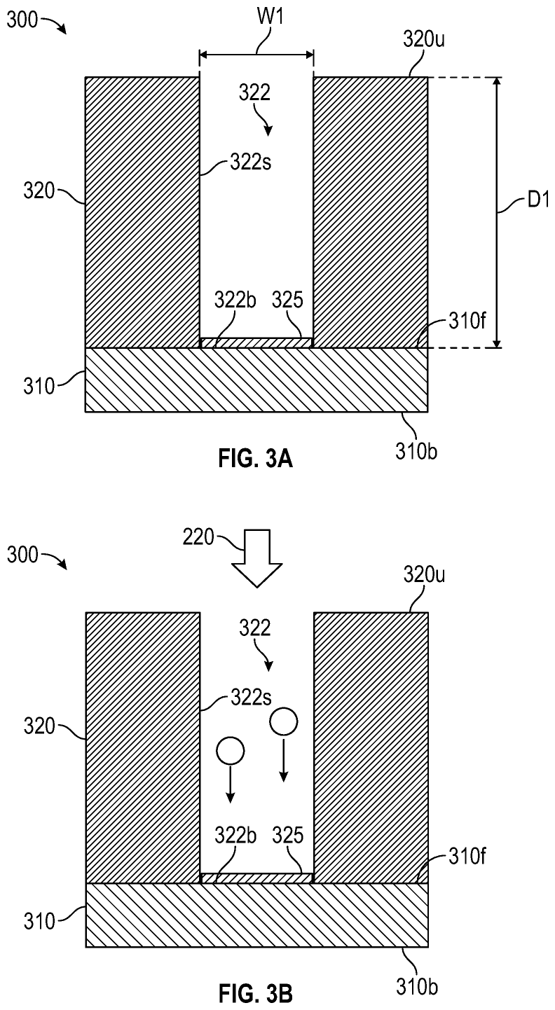

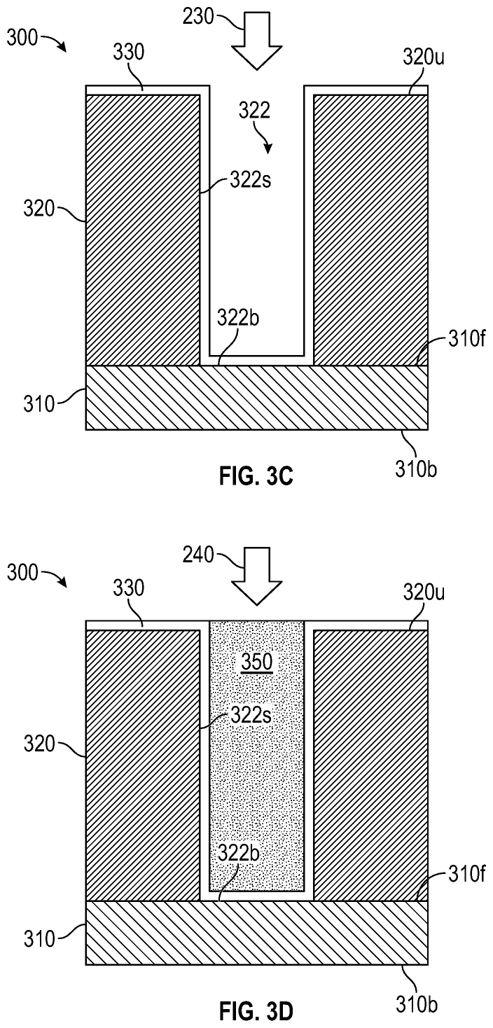

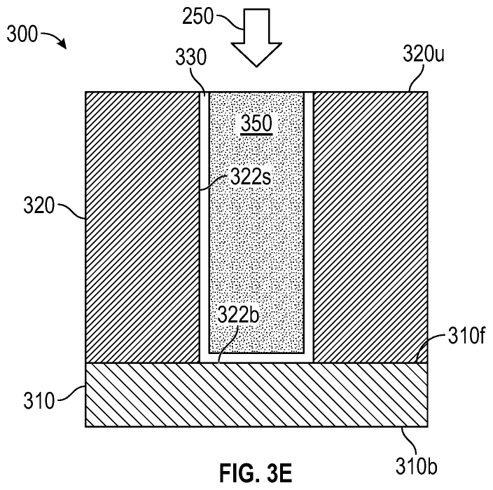

FIGS. 2A-B illustrate flow charts of various methods 200A-B for manufacturing a semiconductor device in accordance with one or more implementations of the present disclosure. FIGS. 3A-3E illustrate views of various stages of manufacturing a semiconductor device in accordance with one or more implementations of the present disclosure. Although FIGS. 3A-3E are described in relation to the methods 200A-B, it will be appreciated that the structures disclosed in FIGS. 3A-3E are not limited to the methods 200A-B, but instead may stand alone as structures independent of the methods 200A-B. Similarly, although the methods 200A-B is described in relation to FIGS. 3A-3E, it will be appreciated that the methods 200A-B is not limited to the structures disclosed in FIGS. 3A-3E but instead may stand alone independent of the structures disclosed in FIGS. 3A-3E. It should be understood that FIGS. 3A-3E illustrate only partial schematic views of the semiconductor device structure 300, and the semiconductor device structure 300 may contain any number of transistor sections and additional materials having aspects as illustrated in the figures. It should also be noted that although the method 200A illustrated in FIG. 2A-2B is described sequentially, other process sequences that include one or more operations that have been omitted and/or added, and/or has been rearranged in another desirable order, fall within the scope of the implementations of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2A, at operation 210, a semiconductor device structure 300 having a feature formed therein is provided. FIG. 3A illustrates a cross-sectional view of the semiconductor device structure 300 during intermediate stages of manufacturing corresponding to the operation 210. The semiconductor device structure 300 includes a device substrate 310 having one or more layers formed thereon, for example, a dielectric layer 320 as is shown in FIG. 3A. The device substrate 310 may be or include a bulk semiconductor substrate, a semiconductor-on-insulator (SOI) substrate, or the like, which may be doped (e.g., with a p-type dopant or an n-type dopant) or undoped. In some implementations, the semiconductor material of the device substrate 310 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 310 may include additional materials, for example, silicide layers, metal silicide layers, metal layers, dielectric layers, etch stop layers, interlayer dielectrics, or a combination thereof.

The device substrate 310 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 310 to generate the structural and functional requirements of the design for the resulting semiconductor device structure 300.

The device substrate 310 has a frontside 310f (also referred to as a front surface) and a backside 310b (also referred to as a back surface) opposite the frontside 310f. The dielectric layer 320 is formed over the frontside 310f of the device substrate 310. The dielectric layer 320 may include multiple layers. The dielectric layer 320 includes an upper surface 320u or field region. In some implementations, the dielectric layer 320 includes a dielectric material, such as a low k dielectric (SiCOH), silicon oxide, silicon dioxide (SiO2), silicon nitride (Si3N4), silicon carbide (SiC), silicon oxynitride (SiON), aluminum oxide (Al2O3), aluminum nitride (AlN), a combination thereof, or multi-layers thereof. In some implementations, the dielectric layer 320 consists essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 320 is patterned to form one or more feature(s) 322. The feature 322 may be a high aspect ratio (HAR) feature. In some implementations, the feature 322 can be selected from a trench, a via, a hole, or a combination thereof. In particular implementations, the feature is a trench. In other particular implementations, the feature 322 is a via. In some implementations, the feature 322 extends from the upper surface 320u of the dielectric layer 320 toward the frontside 310f of the device substrate 310. The feature 322 includes sidewall surface(s) 322s and a bottom surface 322b extending between the sidewall surface(s) 322s. In some implementations, the sidewall surface(s) 322s is tapered. The sidewall surface(s) 322s may be defined by the dielectric layer 320 and the bottom surface may be defined by the device substrate 310. The sidewall surface(s) 322s may be defined by a dielectric material and the bottom surface 322b may be defined by a dielectric material or other materials, for example, a silicide layer, a metal silicide layer, a semiconductor layer, an etch stop layer (ESL), or a metal layer.

In some implementations, the sidewall surface(s) 322s is defined by the dielectric layer 320 and the bottom surface 322b may also be defined by the dielectric layer 320, for example, where the feature 322 is a trench structure. In other implementations, the sidewall surface(s) 322s is defined by the dielectric layer 320 and the bottom surface 322b is defined by a conductive material, for example, where the feature 322 is a via or bottom contact structure. The conductive material may be formed of copper (Cu), cobalt (Co), molybdenum (Mo), tungsten (W), or ruthenium (Ru). The feature 322 has a first depth “D1” from the upper surface 320u to the bottom surface 322b and a width “W1” between the two sidewall surface(s) 322s. In some implementations, the depth D1 is in a range of 2 nm to 200 nm, 3 nm to 200 nm, 5 nm to 100 nm, 2 nm to 100 nm, or 50 nm to 100 nm. In some implementations, the width W1 is in a range of 10 nm to 100 nm, 10 nm to 20 nm, 10 nm to 50 nm, or 50 nm to 100 nm. In some implementations, the feature 322 has an aspect ratio (D/W) in a range of 1 to 20, 5 to 20, 10 to 20, or 15 to 20.

In some implementations, as shown in FIG. 3A, the semiconductor device structure 300 may have a native oxide layer 325 or other contaminants formed on the sidewall surface(s) 322s, the bottom surface 322b, or both the sidewall surface(s) 322sand the bottom surface 322b of the feature 322. The semiconductor device structure 300 may be exposed to atmosphere prior to or during processing, which may lead to the formation of the native oxide layer 325 on the surfaces of the feature and substrate. For example, if a vacuum break occurs prior to or during the method 200A, the vacuum break can lead to the formation of native oxides. In addition, other processes performed prior to or during the method 200A may lead to the formation of additional contaminants or debris on the sidewall surface(s) 322s and the bottom surface 322b of the feature 322.

Referring to FIG. 2A, optionally, at operation 220, the semiconductor device structure 300 is exposed to a pretreatment process. FIG. 3B illustrates a cross-sectional view of a semiconductor device structure 300 during intermediate stages of manufacturing corresponding to the operation 220. The pretreatment process of operation 220 can include one or more native oxide removal processes for removing the native oxide layer 325 (if present). The pretreatment process of operation 220 can include one more dry clean processes. Any suitable dry clean process may be performed. The dry clean process may include a plasma etch process, such as a two-part dry chemical clean process using NF₃ and NH₃, an H2 and O2 plasma etch process, an H2 plasma etch process, or a combination thereof.

In one or more implementations, which can be combined with other implementations, the feature 322 is exposed to a dry clean process and/or a degas process prior to formation of one or more conformal/nonconformal layers including a grain modification layer over the feature during operation 230. The dry clean process may be used to remove oxides from the surface of the feature 322. For example, if the feature 322 includes silicon, the Applied Materials SICONI® clean processes may be performed for removing oxide from the surfaces of the substrate and feature. The SICONI® clean process removes native oxide through a low-temperature, two-part dry chemical clean process using NF₃ and NH₃. The clean process may be performed in a processing chamber positioned on a cluster tool, for example, the processing system 100 (see FIG. 1). Exemplary pre-clean chambers in which the dry clean process of operation 220 may be performed include the SICONI® clean chamber and the Preclean XT chamber available from Applied Materials, Inc., of Santa Clara, Calif.

In one or more implementations, which can be combined with other implementations, the substrate and the feature may be exposed to a fluorine-containing precursor and a hydrogen-containing precursor in a two-part dry chemical clean process. In one or more implementations which can be combined with other implementations, the fluorine-containing precursor may include nitrogen trifluoride (NF₃), hydrogen fluoride (HF), diatomic fluorine (F₂), monatomic fluorine (F), fluorine-substituted hydrocarbons, combinations thereof, or the like. In one or more implementations, which can be combined with other implementations, the hydrogen-containing precursors may include atomic hydrogen (H), diatomic hydrogen (H₂), ammonia (NH₃), hydrocarbons, incompletely halogen-substituted hydrocarbons, combinations thereof, or the like.

In one or more implementations, which can be combined with other implementations, the first part of the two-part dry clean process includes using a remote plasma source to generate an etchant species, for example, ammonium fluoride (NHF₄), from the fluorine-containing precursor, for example, nitrogen trifluoride (NF₃), and the hydrogen-containing precursor, for example, ammonia (NH₃). By using a remote plasma source, damage to the substrate may be minimized. The etchant species may then be introduced into a pre-clean chamber, for example, the processing chamber 120, 122 depicted in FIG. 1, and condensed into a solid by-product on the surface of the substrate through a reaction with the native oxides present on the surface. The second part of the two-part dry clean process may then include an in-situ anneal to decompose the by-product using convection and radiation heating. The by-product then sublimates and may be removed from the surface of the feature via a flow of gas and pumped out of the pre-clean chamber.

In one or more implementations which can be combined with other implementations, the pre-treatment process is a plasma treatment process. The plasma treatment process can be an inductively coupled plasma (ICP) process or a capacitively coupled plasma (CCP) process. The plasma can be formed ex-situ in a remote plasma source (RPS). The plasma can be a direct plasma formed in-situ, for example, generated within a processing region. In one or more implementations, which can be combined with other implementations, the plasma treatment process includes exposing the semiconductor device structure 300 to a plasma formed from a process gas including a hydrogen-containing gas. In one or more implementations, which can be combined with other implementations, the plasma treatment process includes exposing the substrate to a plasma formed from a process gas including both a hydrogen-containing gas and an oxygen-containing gas. In one example, the plasma treatment process includes exposing the feature 322 to an ICP formed from a process gas including a hydrogen-containing gas and an oxygen-containing gas. The process gas may further include an inert gas, for example, argon (Ar), helium (He), krypton (Kr), or a combination thereof. In one or more implementations, which can be combined with other implementations, the plasma treatment process includes exposing the feature to a plasma formed form a process gas including one or more of H₂, O₂, Ar, or a combination thereof. In one or more implementations, which can be combined with other implementations, the plasma treatment process can include exposing the feature to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In one or more implementations, which can be combined with other implementations, the plasma treatment process is performed at temperatures of 400 degrees Celsius or less. In one or more implementations, which can be combined with other implementations, the plasma treatment process includes supplying a processing gas including H2% greater than or equal to 90% of the total flow of hydrogen and oxygen.

Referring to FIG. 2A, at operation 230, a grain modification layer 330 is formed over the feature 322. FIG. 3C illustrates a cross-sectional view of the semiconductor device structure 300 during intermediate stages of manufacturing corresponding to the operation 230. The grain modification layer 330 helps control the grain size of the subsequently deposited molybdenum material. The grain modification layer 330 may be or include a metal layer, a metal, for example, tantalum, cobalt, titanium, tungsten, copper, ruthenium, the like, or a combination thereof. The grain modification layer 330 may be a conformal layer. The grain modification layer 330 may be a nonconformal layer. The grain modification layer 330 may be or include a metal, for example, tantalum, cobalt, titanium, tungsten, copper, ruthenium, the like, or a combination thereof. Although a single layer is depicted the grain modification layer 330 may include one or more additional conformal/nonconformal layers, for example, one or more of barrier, adhesion, and/or grain modification layers. The one or more additional conformal/nonconformal layers can include or be a nitride, for example, silicon nitride, carbon nitride, aluminum nitride, tantalum nitride, titanium nitride, tungsten nitride, the like, or a combination thereof, or a carbide, for example, tungsten carbide, aluminum carbide, the like, or a combination thereof. The grain modification layer 330 may be formed by any suitable deposition process such as ALD, CVD, PVD, or a hybrid ALD/CVD process. The grain modification layer 330 may be formed by a selective vapor deposition process, for example, a selective ALD, a selective CVD, or a selective hybrid ALD/CVD process. The grain modification layer 330 can be molybdenum-free. In one or more implementations, which can be combined with other implementations, the grain modification layer 330 has an initial thickness in a range from about 1 Å to about 100 Å, or in a range from about 10 Å to about 50 Å, or in a range from about 20 Å to about 50 Å, or in a range from about 10 Å to about 20 Å. The grain modification layer 330 may be or include a tungsten layer deposited via a PVD process. The grain modification layer 330 may be or include a tungsten layer deposited via a CVD process.

In one or more implementations, which can be combined with other implementations the grain modification layer 330 is formed over or directly on at least a portion of the at least one feature 322. In some implementations, as is shown in FIG. 3C, the grain modification layer 330 may be formed over or directly on the sidewall surface(s) 322s and the bottom surface 322b of the feature 322 and over or on the upper surface 320u or field region of the dielectric layer 320. In other implementations, the grain modification layer 330 is selectively formed over or on the bottom surface 322b of the feature 322 and the grain modification layer 330 either does not form on or minimally forms on the sidewall surface(s) 322s defined by the dielectric layer 320. In some implementations, the grain modification layer 330 may be or includes a tungsten layer. The tungsten layer may be formed directly on or over the surfaces of the feature 322. The grain modification layer may be or include a tungsten layer having an initial thickness in a range from about 1 Å to about 100 Å, or in a range from about 20 Å to about 50 Å. In some implementations, the grain modification layer 330 may be discontinuous along for example, the sidewall surface(s) 322s and/or the bottom surface 322b.

In one implementation, which can be combined with other implementations, the grain modification layer 330 is formed on the bottom surface 322b by a selective deposition process. The bottom surface 322b may be defined by a metal layer, for example, such as in a metal contact structure. The bottom surface 322b may be defined by the dielectric layer, for example, such as in a layer structure. The selective deposition process may be or include a vapor deposition process performed in a deposition chamber. The selective deposition process may be or include an ALD process, a CVD process, or a hybrid ALD/CVD process. The vapor deposition process may be or include introducing a tungsten halide precursor into the deposition chamber. The tungsten halide precursor may be or include tungsten hexachloride (WCl6), tungsten hexachloride (WCl5), or a combination thereof. The vapor deposition process may be or include introducing a cobalt precursor into the deposition chamber. The cobalt precursor may be or include dicobalt hexacarbonyl acetyl compounds, for example, dicobalt hexacarbonyl butylacetylene (CCTBA, CO₂(CO)₆[HC≡C(CH3)3)]. The vapor deposition process may be or further include introducing a reducing agent precursor gas into the deposition chamber. The reducing agent precursor gas is selected from molecular hydrogen (H₂), hydrogen atoms, a hydrogen plasma, hydrogen radicals, hydrogen excited species, or a combination thereof. In one example, the selective vapor deposition process includes introducing H2 and WCl5 into the deposition chamber. In another example, the selective vapor deposition process includes introducing H2 and CCTBA into the deposition chamber.

Referring to FIG. 2A, at operation 240, the feature 322 is filled with molybdenum-fill material 350. FIG. 3D illustrates a cross-sectional view of the semiconductor device structure 300 during intermediate stages of manufacturing corresponding to the operation 240. The molybdenum-fill material 350 can be formed by bottom-up growth or conformal growth. For example, in some implementations where the grain modification layer 330 is selectively formed on the bottom surface 322b, the molybdenum-fill material 350 is formed by bottom-up growth. In some implementations where the grain modification layer 330 is formed on the sidewall surface(s) 322s and the bottom surface 322b, the molybdenum-fill material 350 is formed by conformal growth. The molybdenum-fill material 350 may be formed by any suitable deposition process such as ALD, CVD, PVD, or a hybrid ALD/CVD process. Precursors used during the deposition process may include molybdenum-containing precursors selected from molybdenum chlorides (e.g., MoClx, where x=2-6), molybdenum fluorides (MoF6), molybdenum oxyhalides (e.g., MoO2Cl2, MoOCl4). In some implementations, the molybdenum chloride can be or include molybdenum (II) chloride, molybdenum (III) chloride, molybdenum (IV) chloride, molybdenum (V) chloride, molybdenum (IV) chloride, or a combination thereof. In particular implementations, the molybdenum chloride precursor can be or include molybdenum (V) chloride that is molybdenum pentachloride (MoCl5). Suitable examples of the metal containing precursor include Mo(NMe₂)₄, MoCl₅, MoF₆, tetramethylheptane-3,5-dionato (Mo(thd)₃), Mo(CO)₆, and the like.

In some implementations, molybdenum-fill material 350 is deposited using a CVD process including concurrently flowing (co-flowing) a molybdenum-containing precursor gas, a reducing agent, and optionally a carrier gas into a processing region and exposing the semiconductor device structure 300 thereto. The molybdenum-containing precursor and the reducing agent used for the molybdenum-fill CVD process may include any combination of the molybdenum-containing precursors and reducing agents described herein. In particular implementations, the molybdenum-containing precursor includes MoCl₅, and the reducing agent includes hydrogen gas. In some implementations, the molybdenum-fill material 350 partially fills the feature 322.

In some implementations, during the molybdenum-fill CVD process of operation 240 the molybdenum-containing precursor is flowed into the processing region at a flow rate in a range from about 10 sccm to about 1200 sccm, or more than about 50 sccm, or less than about 1000 sccm, or in a range from about 100 sccm to about 900 sccm. The reducing agent is flowed into the processing region at a rate of more than about 500 sccm, such as more than about 750 sccm, more than about 1000 sccm, or in a range from about 500 sccm and about 10000 sccm, such as in a range from about 1000 sccm to about 9000 sccm, or in a range from about 1000 sccm and about 8000 sccm. The carrier gas may be flowed into the processing region at a flow rate in a range from about 10 sccm to about 1200 sccm, or more than about 50 sccm, or less than about 1000 sccm, or in a range from about 100 sccm to about 900 sccm.

In some implementations, the molybdenum-fill CVD process conditions of operation 240 are selected to provide a molybdenum feature having a relativity low residual film stress when compared to conventional molybdenum CVD processes. For example, in some implementations, the molybdenum-fill CVD process includes heating the substrate at a temperature of about 250° C. or more, such as about 300° C. or more, or in a range from about 250° C. to about 500° C., or in a range from about 300° C. to about 500° C., or in a range from about 400° C. to about 500° C., or in a range from about 450° C. to about 500° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In some implementations, the molybdenum-fill material 350 is deposited using a PVD process.

In other implementations, the molybdenum-fill material 350 is deposited at operation 240 using an atomic layer deposition (ALD) process. The molybdenum-fill ALD process includes repeating cycles of alternately exposing the semiconductor device structure 300 to a molybdenum-containing precursor gas and a reducing agent and purging the processing region between the alternating exposures.

The molybdenum-containing precursor and the reducing agent are each flowed into the processing region for a duration of between about 0.1 seconds and about 10 seconds, such as between about 0.5 seconds and about 5 seconds. The processing region may be purged between the alternating exposures by flowing an inert purge gas, such as argon (Ar) or hydrogen, into the processing region for a duration in a range from about 0.1 seconds to about 10 seconds, such as in a range from about 0.5 seconds to about 5 seconds.

In other implementations, the molybdenum-fill material 350 is deposited using a pulsed CVD method that includes repeating cycles of alternately exposing the semiconductor device structure 300 to a molybdenum-containing precursor gas and a reducing gas without purging the processing region. The processing conditions for the molybdenum-fill pulsed CVD method may be the same, substantially the same, or within the same ranges as those described above for the tungsten gap-fill ALD process.

Referring to FIG. 2A, optionally at operation 250, the semiconductor device structure 300 is exposed to additional processing. FIG. 3E illustrates a cross-sectional view of the semiconductor device structure 300 during intermediate stages of manufacturing corresponding to the operation 250. In some implementations, a planarization process, for example a CMP process or an etchback process may be performed to remove excess portions or overburden of the molybdenum-fill material (if present). For example, as shown in FIG. 3E, portions of the molybdenum-fill material 350 and the grain modification layer 330 are planarized to expose the upper surface 320u of the dielectric layer 320. In some implementations, an annealing process may be performed during operation 250.

Referring to FIG. 2B, the method 200B depicts another sequence of operations. The method 200B is similar to the method 200A, except that the method 200B includes a vacuum break after formation of the grain modification layer 330 during operation 230 and prior to the molybdenum fill of operation 240. During the vacuum break oxides may form on the deposited grain modification layer 330, for example, tungsten oxides. Thus, the deposited grain modification layer 330 is exposed to the pretreatment process of operation 220 after formation of the grain modification layer 330 during operation 230 and prior to deposition of the molybdenum-fill material of operation 240.

In summary, the previously described implementations of the present disclosure have many advantages, including low resistivity metal contact fill, which enables device scaling in features with ultra-high aspect ratios. Molybdenum films grown by themselves typically have a small grain size, which contributes to a higher resistivity. In addition, some structures lack contact metal, which provides the conditions for low resistivity molybdenum growth. Various implementations described provide a metal layer, for example, a tungsten layer or a cobalt layer on which the molybdenum-fill is grown. Not to be bound by theory but it is believed that the metal layers described enable larger molybdenum grain size, which helps achieve lower resistivity. The metal layer may be deposited using techniques such as PVD, CVD, ALD, or hybrid ALD/CVD techniques. The molybdenum-fill may be deposited by CVD or PVD. The molybdenum-fill may be bottom-up or conformal. The processes described can achieve low resistivity molybdenum-fill regardless of structure type, for example, a via with a metal contact or a trench which has no metal contact. However, the present disclosure does not necessitate that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof, for example, “including” and “having,” are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility). In addition some of the operations described in the methods 200A-B may be omitted unless stated otherwise.

When introducing elements of the present disclosure or exemplary aspects or implementation(s) thereof, the articles “a,” “an,” “the” and “said” are intended to mean that there are one or more of the elements.

While the foregoing is directed to implementations of the present disclosure, other and further implementations of the disclosure may be devised without departing from the basic scope thereof, and the scope thereof is determined by the claims that follow.

1. A method for processing a semiconductor device substrate, comprising:
exposing at least one feature formed in a dielectric layer to a grain modification layer deposition process to deposit a grain modification layer over at least a portion of the at least one feature, and the at least one feature is defined by sidewall surfaces formed in the dielectric layer and a bottom surface extending between the sidewall surfaces; and
exposing the at least one feature to a molybdenum deposition process to form a molybdenum-fill layer on the grain modification layer, wherein the grain modification layer comprises a metal different from molybdenum.

2. The method of claim 1, wherein the grain modification layer deposition process is a physical vapor deposition (PVD) process and the metal comprises tungsten.

3. The method of claim 1, wherein the molybdenum deposition process is a physical vapor deposition (PVD) process.

4. The method of claim 1, wherein the molybdenum deposition process comprises a vapor deposition process performed in a deposition chamber.

5. The method of claim 4, wherein the vapor deposition process comprises introducing a molybdenum chloride precursor, a molybdenum oxyhalide precursor, or a combination thereof into the deposition chamber.

6. The method of claim 5, wherein the vapor deposition process further comprises introducing a reducing agent precursor gas into the deposition chamber.

7. The method of claim 6, wherein the reducing agent precursor gas is selected from molecular hydrogen (H₂), hydrogen atoms, a hydrogen plasma, hydrogen radicals, hydrogen excited species or a combination thereof.

8. The method of claim 4, wherein the vapor deposition process comprises introducing H2and MoCl5 into the deposition chamber.

9. The method of claim 1, wherein the bottom surface is defined by the dielectric layer.

10. The method of claim 1, wherein the bottom surface is defined by a silicide layer, a metal silicide layer, or a metal layer.

11. A method for processing a semiconductor device structure, comprising:
exposing at least one feature formed in a dielectric layer formed over a substrate to a physical vapor deposition (PVD) process to deposit a grain modification layer comprising tungsten over at least a portion of the at least one feature, wherein the PVD process is performed in a first processing region of a first processing chamber and the at least one feature is defined by sidewall surfaces formed in the dielectric layer and a bottom surface extending between the sidewall surfaces;
transferring the substrate from the first processing region of the first processing chamber to a second processing region of a second processing chamber without breaking vacuum; and
exposing the feature to a vapor deposition process comprising flowing a molybdenum-containing precursor gas into the second processing region to form a molybdenum-fill layer on the grain modification layer within the at least one feature in the second processing region.

12. The method of claim 11, wherein the molybdenum-containing precursor gas is selected from a molybdenum chloride precursor, a molybdenum oxyhalide precursor, or a combination thereof.

13. The method of claim 11, wherein the vapor deposition process further comprises introducing a reducing agent precursor gas into the deposition chamber.

14. The method of claim 13, wherein the reducing agent precursor gas is selected from molecular hydrogen (H₂), hydrogen atoms, a hydrogen plasma, hydrogen radicals, hydrogen excited species or a combination thereof.

15. The method of claim 11, wherein the vapor deposition process comprises introducing H2 and MoCl5 into the second processing region.

16. The method of claim 11, wherein the vapor deposition process is performed at a temperature in a range from about 400° C. to about 500° C. at a pressure in a range from about 1 Torr to about 100 Torr.

17. The method of claim 11, wherein the vapor deposition process is a chemical vapor deposition (CVD) process, an atomic layer deposition (ALD) process, or a plasma-enhanced ALD process.

18. A semiconductor device structure, comprising:
a device substrate having a frontside and a backside;
a dielectric layer formed over the device substrate, the dielectric layer having at least one feature formed therein, the at least one feature defined by sidewall surfaces defined by the dielectric layer and a bottom surface extending between the sidewall surfaces;
a grain modification layer comprising tungsten formed on at least the bottom surface of the feature; and
a molybdenum-fill material contacting the grain modification layer and filling the feature.

19. The device structure of claim 18, wherein the grain modification layer has a thickness in a range from about 10 Å to about 50 Å.

20. The devices structure of claim 18, wherein the bottom surface is defined by the dielectric layer and the grain modification layer is formed on the sidewall surfaces defined by the dielectric layer.
